(19) United States
(12) Patent Application Publication
(10) Pub. No.: US 2007/0223196 A1
(43) Pub. Date: Sep. 27, 2007

(54) Composite heatsink plate assembly

(76) Inventors: Ming-Sho Kuo, Tao Yuan Hsien (TW); Erh-Wen Kuo, Tao Yuan Hsien (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 11/386,568

(22) Filed: Mar. 22, 2006

(51) Int. Cl. H05K 7/20

(52) U.S. Cl. 361/710

(57) ABSTRACT

A heatsink plate assembly includes a plurality of heatsink plates laminating each other. Each of the heatsink plates has a first side formed with at least one locking tenon and a second side formed with at least one locking mortise. Thus, the heatsink plates are laminated to have a determined width required by the heatsink plate assembly, so that the width of the heatsink plate assembly is increased according to the user's requirement without being limited to the width of the extruding machine, thereby facilitating fabrication of the heatsink plate assembly. In addition, each of the heatsink plates is made at a time without needing multiple working procedures, so that each of the heatsink plates is produced easily and rapidly, thereby decreasing costs of fabrication.

### BACKGROUND OF THE INVENTION

1. Field of the Invention

The present invention relates to a heatsink plate assembly and, more particularly, to a composite heatsink plate assembly.

2. Description of the Related Art

A conventional heatsink plate 2 in accordance with the prior art shown in FIG. 10 is integrally formed by an extruding process. In general, the heatsink plate 2 is formed by an extruding machine having a larger size. However, the extruding machine having a larger size has a higher price, thereby increasing costs of fabrication. In addition, the width and height of the extruding machine is limited.

Alternatively, a plurality of smaller plates are formed by an extruding machine having a smaller size, and the smaller plates are packed by a hydraulic machine or by a punching press to form the heatsink plate 2. However, production of the heatsink plate 2 needs more working procedures, thereby greatly increasing costs of fabrication.

### BRIEF SUMMARY OF THE INVENTION

In accordance with the present invention, there is provided a heatsink plate assembly, comprising a plurality of heatsink plates laminating each other. Each of the heatsink plates has a first side formed with at least one locking tenon and a second side opposite to the first side and formed with at least one locking mortise. The locking tenons of each of the heatsink plates are inserted into and locked in the locking mortises of an adjacent heatsink plate respectively, so that the heatsink plates are laminated and combined with each other to form the heatsink plate assembly.

The primary objective of the present invention is to provide a composite heatsink plate assembly consisting of a plurality of heatsink plates laminating each other.

Another objective of the present invention is to provide a heatsink plate assembly, wherein the heatsink plates are laminated to have a determined width required by the heatsink plate assembly, so that the width of the heatsink plate assembly is increased according to the user's requirement without being limited to the width of the extruding machine, thereby facilitating fabrication of the heatsink plate assembly.

A further objective of the present invention is to provide a heatsink plate assembly, wherein each of the heatsink plates is made at a time without needing multiple working procedures, so that each of the heatsink plates is produced easily and rapidly, thereby decreasing costs of fabrication.

A further objective of the present invention is to provide a heatsink plate assembly, wherein each of the heatsink plates has a smaller size, so that each of the heatsink plates is made by the extruding machine easily and rapidly, to prevent the extruding machine from being worn out or inoperative due to an excessive size, thereby enhancing the working efficiency and the lifetime of the extruding machine.

A further objective of the present invention is to provide a heatsink plate assembly, wherein the width of the heatsink plate assembly can be adjusted arbitrarily according to the user's requirement, thereby enhancing the versatility of the heatsink plate assembly.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a side plan view of a heatsink plate assembly in accordance with the preferred embodiment of the present invention.

FIG. 2 is a perspective view of a heatsink plate of the heatsink plate assembly as shown in FIG. 1.

FIG. 3 is a side plan view of the heatsink plate as shown in FIG. 2.

FIG. 4 is a side plan view of a heatsink plate in accordance with another preferred embodiment of the present invention.

FIG. 5 is a side plan view of a heatsink plate in accordance with another preferred embodiment of the present invention.

FIG. 6 is a side plan view of a heatsink plate assembly in accordance with another preferred embodiment of the present invention.

FIG. 7 is a side plan view of a heatsink plate of the heatsink plate assembly as shown in FIG. 6.

FIG. 8 is a side plan view of a heatsink plate assembly in accordance with another preferred embodiment of the present invention.

FIG. 9 is a side plan view of a heatsink plate of the heatsink plate assembly as shown in FIG. 8.

FIG. 10 is a side plan view of a conventional heatsink plate in accordance with the prior art.

### DETAILED DESCRIPTION OF THE INVENTION

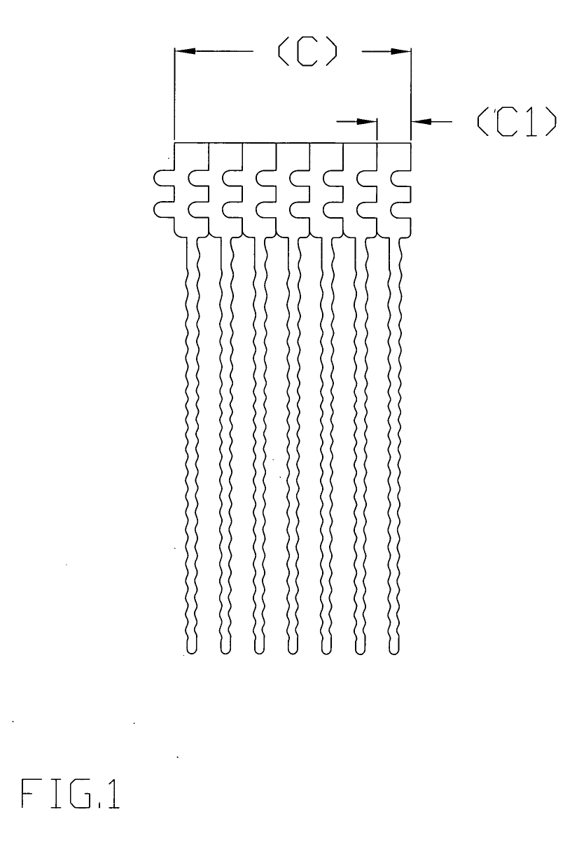

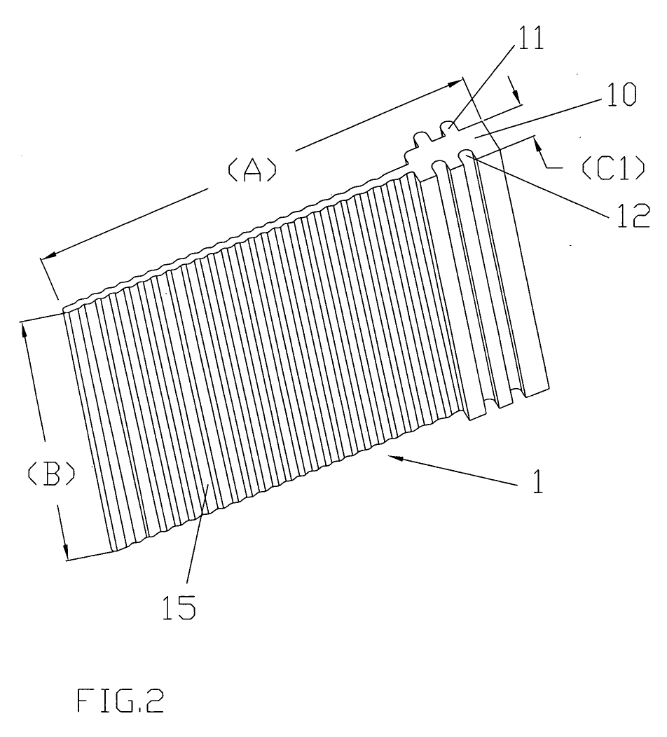

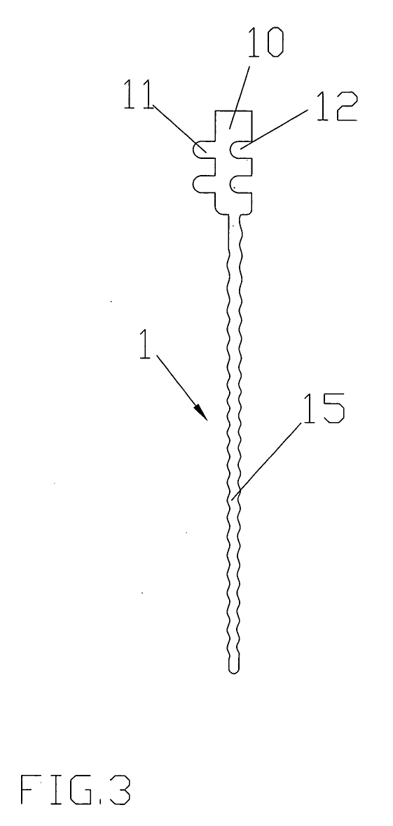

Referring to the drawings and initially to FIGS. 1-3, a composite heatsink plate assembly in accordance with the preferred embodiment of the present invention comprises a plurality of heatsink plates 1 laminating each other as shown in FIG. 3.

Each of the heatsink plates 1 is integrally formed by an extruding process. Each of the heatsink plates 1 has a length (A) equal to that of the heatsink plate assembly and has a height (B) equal to that of the heatsink plate assembly. Each of the heatsink plates 1 has a width (C1), and the heatsink plates 1 are laminated to have a width (C) equal to that of the heatsink plate assembly as shown in FIG. 3.

Each of the heatsink plates 1 has a first side formed with at least one locking tenon 11 and a second side opposite to the first side and formed with at least one locking mortise 12. In the preferred embodiment of the present invention, each of the heatsink plates 1 has a plurality of locking tenons 11 and a plurality of locking mortises 12, and the locking tenons 11 and the locking mortises 12 of each of the heatsink plates 1 are arranged symmetrically. Each of the heatsink plates 1 has a first end portion 10, and the locking tenon 11 and the locking mortise 12 of each of the heatsink plates 1 are formed on the first end portion 10 of each of the heatsink plates 1. Each of the heatsink plates 1 has a second end portion formed with a cooling fin 15 having a width smaller than that of the first end portion 10 of each of the heatsink plates 1.

In assembly, the locking tenons 11 of each of the heatsink plates 1 are inserted into and locked in the locking mortises 12 of an adjacent heatsink plate 1 respectively, so that the heatsink plates 1 are laminated and combined with each other to form the heatsink plate assembly as shown in FIG. 3.

Accordingly, the heatsink plates 1 are laminated to have a determined width required by the heatsink plate assembly, so that the width of the heatsink plate assembly is increased according to the user's requirement without being limited to the width of the extruding machine, thereby facilitating fabrication of the heatsink plate assembly. In addition, each of the heatsink plates 1 is made at a time without needing multiple working procedures, so that each of the heatsink plates 1 is produced easily and rapidly, thereby decreasing costs of fabrication. Further, each of the heatsink plates 1 has a smaller size, so that each of the heatsink plates 1 is made by the extruding machine easily and rapidly, to prevent the extruding machine from being worn out or inoperative due to an excessive size, thereby enhancing the working efficiency and the lifetime of the extruding machine. Further, the width of the heatsink plate assembly can be adjusted arbitrarily according to the user's requirement, thereby enhancing the versatility of the heatsink plate assembly.

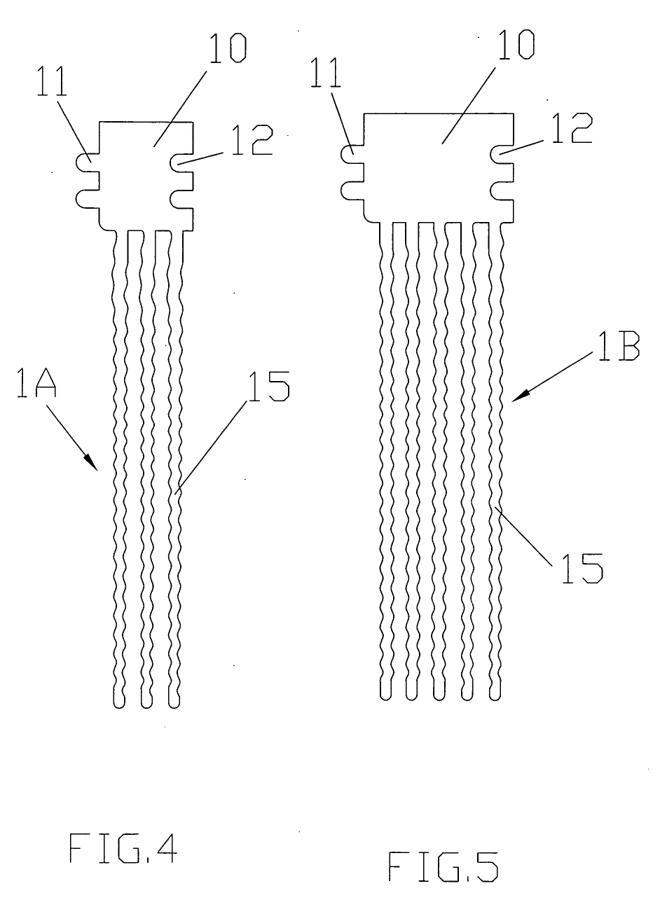

As shown in FIGS. 4 and 5, each of the heatsink plates 1A or 1B has a second end portion formed with a plurality of cooling fins 15 each having a width smaller than that of the first end portion 10 of each of the heatsink plates 1.

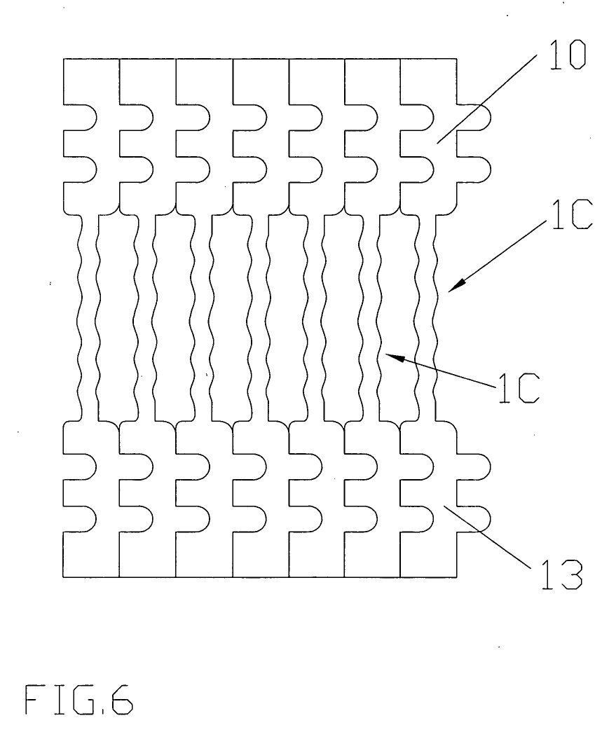

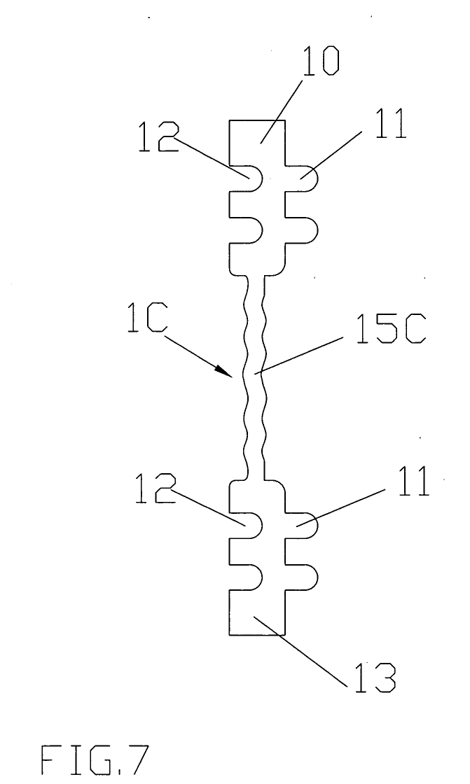

As shown in FIGS. 6 and 7, each of the heatsink plates 1C has a second end portion 13, and the locking tenon 11 and the locking mortise 12 of each of the heatsink plates 1C are also formed on the second end portion 13 of each of the heatsink plates 1C. Each of the heatsink plates 1C has a mediate portion formed with a cooling fin 15C having a width smaller than that of each of the first end portion 10 and the second end portion 13 of each of the heatsink plates 1C.

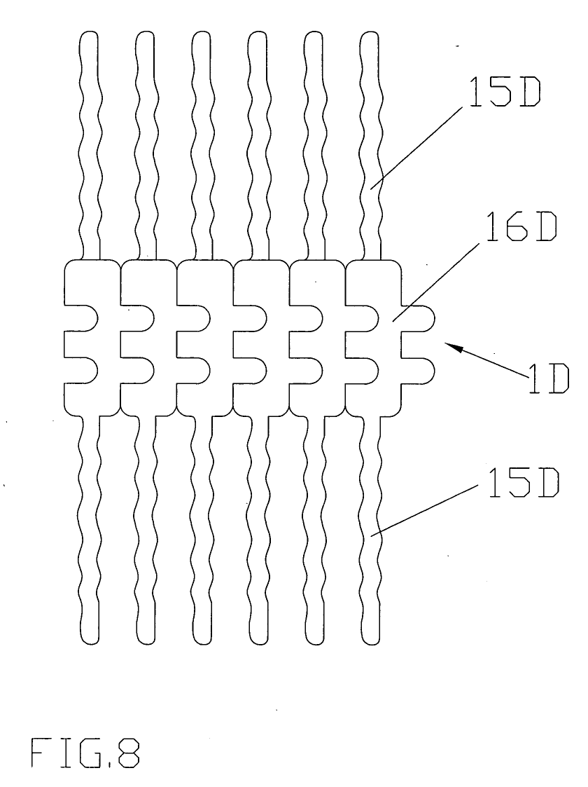

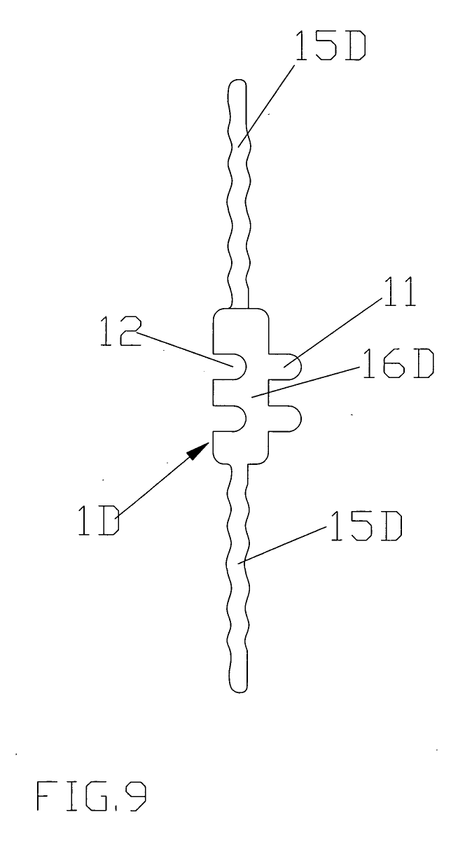

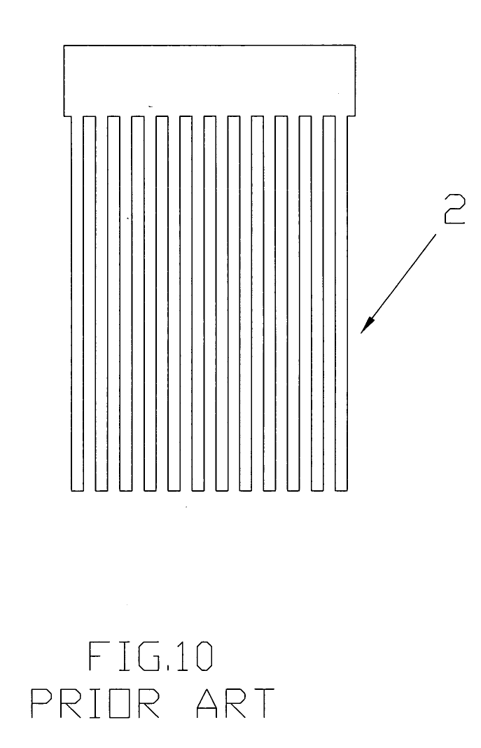

As shown in FIGS. 8 and 9, each of the heatsink plates 1D has a mediate portion 16D, and the locking tenon 11 and the locking mortise 12 of each of the heatsink plates 1D are formed on the mediate portion 16D of each of the heatsink plates 1D. Each of the heatsink plates 1D has a first end portion and a second end portion each formed with a cooling fin 15D having a width smaller than that of the mediate portion 16D of each of the heatsink plates 1D.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A heatsink plate assembly, comprising:
a plurality of heatsink plates laminating each other.

2. The heatsink plate assembly in accordance with claim 1, wherein each of the heatsink plates has a first side formed with at least one locking tenon and a second side opposite to the first side and formed with at least one locking mortise.

3. The heatsink plate assembly in accordance with claim 2, wherein each of the heatsink plates has a plurality of locking tenons and a plurality of locking mortises.

4. The heatsink plate assembly in accordance with claim 3, wherein the locking tenons and the locking mortises of each of the heatsink plates are arranged symmetrically.

5. The heatsink plate assembly in accordance with claim 2, wherein each of the heatsink plates has a first end portion, and the locking tenon and the locking mortise of each of the heatsink plates are formed on the first end portion of each of the heatsink plates.

6. The heatsink plate assembly in accordance with claim 5, wherein each of the heatsink plates has a second end portion formed with a cooling fin.

7. The heatsink plate assembly in accordance with claim 6, wherein the cooling fin has a width smaller than that of the first end portion of each of the heatsink plates.

8. The heatsink plate assembly in accordance with claim 3, wherein the locking tenons of each of the heatsink plates are inserted into and locked in the locking mortises of an adjacent heatsink plate respectively, so that the heatsink plates are laminated and combined with each other to form the heatsink plate assembly.

9. The heatsink plate assembly in accordance with claim 5, wherein each of the heatsink plates has a second end portion formed with a plurality of cooling fins.

10. The heatsink plate assembly in accordance with claim 9, wherein each of the cooling fins has a width smaller than that of the first end portion of each of the heatsink plates.

11. The heatsink plate assembly in accordance with claim 5, wherein each of the heatsink plates has a second end portion, and the locking tenon and the locking mortise of each of the heatsink plates are formed on the second end portion of each of the heatsink plates.

12. The heatsink plate assembly in accordance with claim 11, wherein each of the heatsink plates has a mediate portion formed with a cooling fin.

13. The heatsink plate assembly in accordance with claim 12, wherein the cooling fin has a width smaller than that of each of the first end portion and the second end portion of each of the heatsink plates.

14. The heatsink plate assembly in accordance with claim 2, wherein each of the heatsink plates has a mediate portion, and the locking tenon and the locking mortise of each of the heatsink plates are formed on the mediate portion of each of the heatsink plates.

15. The heatsink plate assembly in accordance with claim 14, wherein each of the heatsink plates has a first end portion and a second end portion each formed with a cooling fin.

16. The heatsink plate assembly in accordance with claim 15, wherein the cooling fin has a width smaller than that of the mediate portion of each of the heatsink plates.

17. The heatsink plate assembly in accordance with claim 1, wherein each of the heatsink plates 1 has a length equal to that of the heatsink plate assembly and has a height equal to that of the heatsink plate assembly.

18. The heatsink plate assembly in accordance with claim 1, wherein each of the heatsink plates has a width, and the heatsink plates are laminated to have a width equal to that of the heatsink plate assembly.

19. The heatsink plate assembly in accordance with claim 1, wherein the heatsink plate assembly has an adjustable width.

20. The heatsink plate assembly in accordance with claim 1, wherein each of the heatsink plates is integrally formed by an extruding process.
